(19) United States
(12) Patent Application Publication
(10) Pub. No.: US 2007/0252167 A1
(43) Pub. Date: Nov. 1, 2007

(54) Surface mounting optoelectronic device

(75) Inventors: Chung-Fu Chen, Tu Chen City (TW); Cheng-Yi Chang, Chung Ho City (TW); Chih-Chia Tsai, Tu Chen City (TW)

Correspondence Address: BIRCH STEWART KOLASCH & BIRCH, PO BOX 747, FALLS CHURCH, VA, 22040-0747, US

(73) Assignee: Everlight Electronics Co., Ltd.

(21) Appl. No.: 11/600,126

(22) Filed: Nov. 16, 2006

(30) Foreign Application Priority Data
Apr. 26, 2006 (TW) 95114946

(51) Int. Cl. H01L 33/00

(52) U.S. Cl. 257/99

(57) ABSTRACT

A surface mounting optoelectronic device is provided. The surface mounting optoelectronic device comprises a circuit board, a conductive layer, an auto-focus LED chip, a flash LED chip, a reflector and an encapsulant. The auto-focus LED chip and the flash LED chip are located on the conductive layer. The reflector is located on the edge of the circuit board. The encapsulant is filled into the reflector to hermetically seal the auto-focus LED chip and the flash LED chip.

### RELATED APPLICATIONS

The present application is based on, and claims priority from, Taiwan Application Serial Number 95114946, filed Apr. 26, 2006, the disclosure of which is hereby incorporated by reference herein in its entirety.

### BACKGROUND

1. Field of Invention

The present invention relates to a surface mounting optoelectronic device of light emitting diode (LED). More particularly, the present invention relates to a surface mounting optoelectronic device with two LED chips.

2. Description of Related Art

A LED is a junction diode mainly composed of p type and n type epitaxy layers on the semiconductor substrate. After forming the epitaxy structure, the chip is sliced and then fixed on the panel. Then, the chip is wired and packaged to form the LED. Generally speaking, the material for packaging the LED is epoxy resin.

The LED has a variety of types and applications. Hence, it has already become an essential tool in the modern world. The LED is generally used as the light source for operation panels of electric appliances, such as the light source of a bar code reader, and the light source of a camera with an auto-focus function or a flash function.

Traditional cameras with the auto-focus and flash function fabrication methods initially require an auto-focus LED chip and a flash LED chip to be manufactured first. Then, the auto-focus LED chip and the flash LED chip are respectively packaged on two circuit boards to finish the multi-functional camera. That is, the auto- focus LED chip and the flash LED chip are respectively fabricated from different package processes. Optoelectronics technologies have recently progressed by leaps and bounds and the lightweight, high quality requirements for cameras has further pushed the demand so that packaging methods of two different LED chips, such as the auto-focus LED chip and the flash LED chip, on the same circuit board to increase space utilization is thus very important. However, to package the two different LED chips on one circuit board, the brightness of the auto-focus LED chip is not enough, about 5 candela (cd), and thus the utility of the products would be decreased.

Thus, there is a need to provide a LED package structure to solve these problems.

### SUMMARY

In one aspect, this present invention provides a surface mounting optoelectronic device to enhance space utilization.

In another aspect, this present invention provides a surface mounting optoelectronic device to decrease material cost and manufacturing cost.

In accordance with the foregoing and other aspects of the present invention, the present invention provides a surface mounting optoelectronic device. The surface mounting optoelectronic device comprises a circuit board, a conductive layer, at least an auto-focus LED chip, at least a flash LED chip, a reflector and an encapsulant. The conductive layer is located on the circuit board. The auto-focus LED chip and the flash LED chip electrically connect the conductive layer. The reflector is located on the edge of the circuit board to package the auto-focus LED chip and the flash LED chip therein. The encapsulant is filled in the reflector to hermetically seal the auto-focus LED chip and the flash LED chip.

According to one embodiment of the present invention, different LED chip structures can be used to adjust electrical connection methods of the auto-focus LED chip and the flash LED chip on the circuit board. Furthermore, numbers of the flash LED chips can be increased according to demands to improve brightness of the flash LED chip.

Thus, the auto-focus LED chip and the flash LED chip are packaged on the same circuit board so that the present invention not only can save more space, but also enhance the brightness of the auto-focus LED chip by 50%. Moreover, the present invention can decrease material cost and manufacturing cost. The total decreased cost is about 20%. Furthermore, the present invention can obtain multi-function illumination effects on one circuit board and increase the number of LED chips to improve its brightness.

### BRIEF DESCRIPTION OF THE DRAWINGS

The invention can be more fully understood by reading the following detailed description of the preferred embodiment, with reference made to the accompanying drawings as follows:

FIGS. 1 and 2 are diagrams showing two different LED chip structures according to one embodiment of the present invention.

FIG. 3 is a cross-sectional diagram showing a surface mounting optoelectronic device according to one embodiment of the present invention.

FIG. 4 is a top-view diagram showing the surface mounting optoelectronic device in FIG. 3 according to one embodiment of the present invention.

FIG. 5 is a top-view diagram showing a surface mounting optoelectronic device according to one embodiment of the present invention.

FIG. 6 is a top-view diagram showing a surface mounting optoelectronic device according to one embodiment of the present invention.

### DETAILED DESCRIPTION

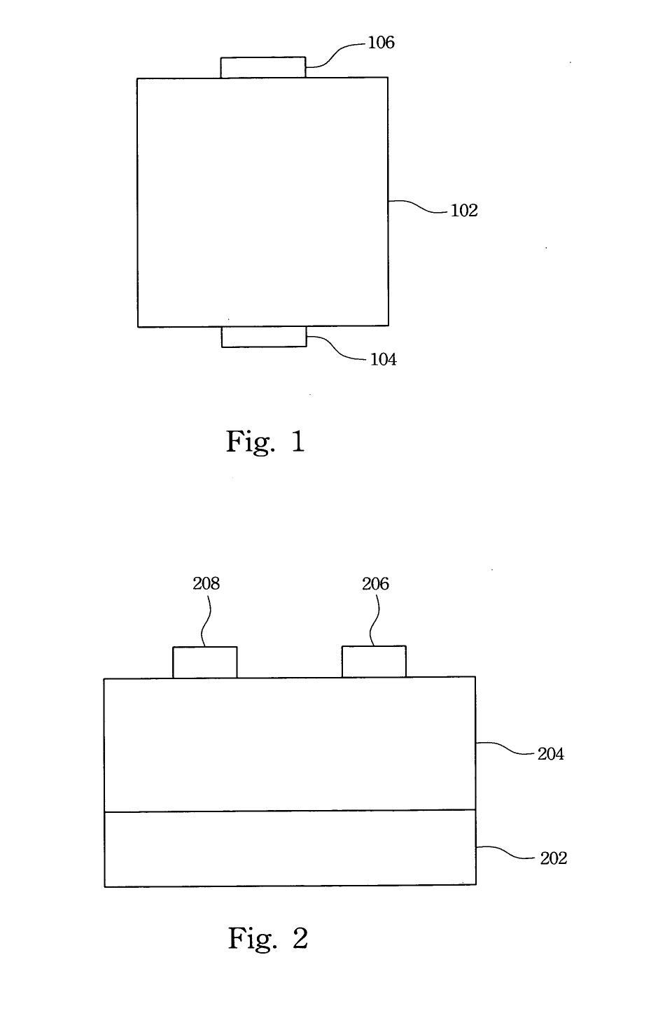

The present invention provides a surface mounting optoelectronic device to improve space utility. FIG. 1 and 2 are diagrams showing two different LED chip structures according to one embodiment of the present invention. In FIG. 1, p-electrode 106 and n-electrode 104 are respectively located on an upper surface and a lower surface of a LED chip 102. Another LED chip structure shown in FIG. 2 comprises a substrate 202, a LED 204, p-electrode 206 and n-electrodes 208. The p-electrode 206 and the n-electrode 208 are located on the same side.

The following description describes three different layouts according to two embodiments of the present invention. However, the present invention can also use other layouts to package the LED chips.

### Embodiment 1

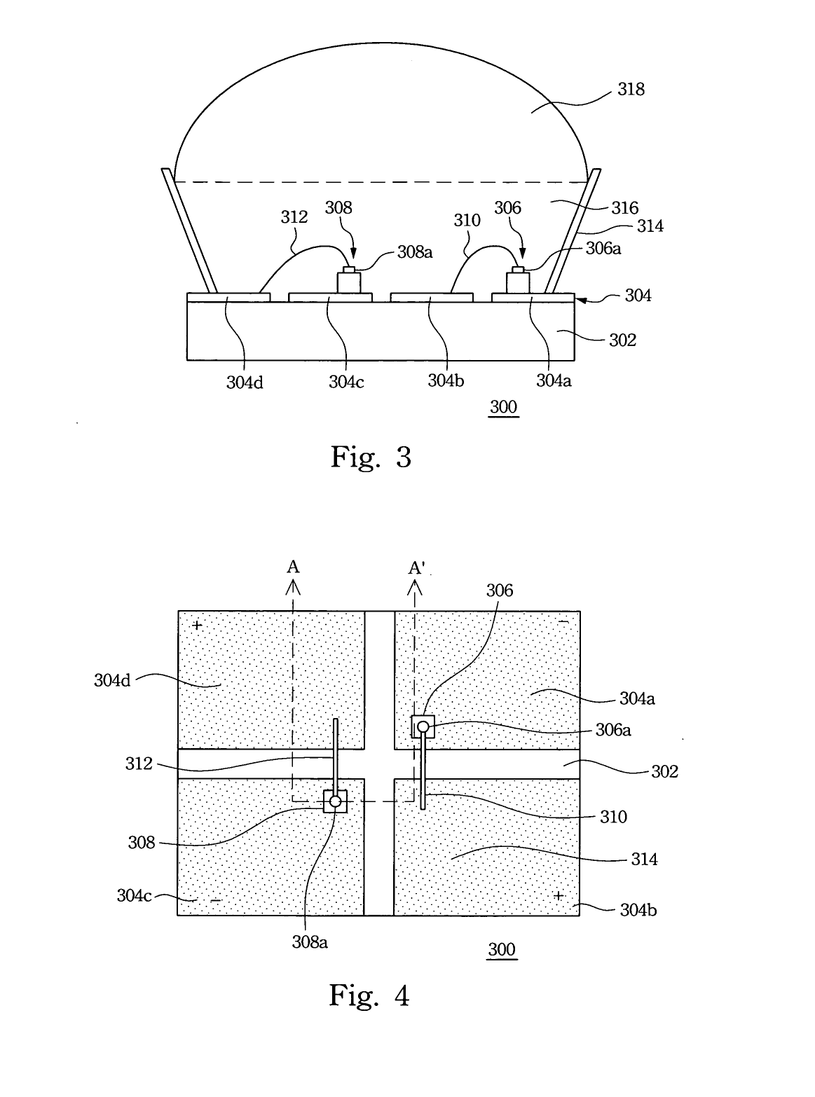

According to one embodiment of the present invention, the LED structure shown in FIG. 1 is used as the auto-focus LED chip and flash LED chip. FIG. 3 is a cross-sectional diagram showing a surface mounting optoelectronic device according to one embodiment of the present invention. In FIG. 3, a surface mounting optoelectronic device 300 comprises a circuit board 302, a conductive layer 304, an auto-focus LED chip 306, a flash LED chip 308, conductive wires 310/312, a reflector 314 and an encapsulant 316. The conductive layer 304 is located on the circuit board 302. According to one embodiment of the present invention, the conductive layer 304 is divided into a first conductive area 304a, a second conductive area 304b, a third conductive area 304c and a fourth conductive area 304d. The four conductive areas (304a, 304b, 304c and 304d) are not connected to each other. According to one embodiment of the present invention, electric charge of the first conductive area 304a and the third conductive area 304c is negative, and the electric charge of the second conductive area 304b and the fourth conductive area 304d is positive. Conductive layer 304 material is preferably Au, Ag, Cu, Pt, Al, Sn or Mg.

FIG. 4 is a top-view diagram showing the surface mounting optoelectronic device in FIG. 3 according to one embodiment of the present invention. But, the reflector 314 and encapsulant 316 in FIG. 3 are not shown in FIG. 4. In other words, FIG. 3 is a cross-section diagram along the A-A′ line of FIG. 4. In FIG. 4, the auto-focus LED chip 306 is preferably located on the first conductive area 304a. The n-electrode of the auto-focus LED chip 306 (not shown in FIG. 4) electrically connects the first conductive area 304a and the p-electrode 306a electrically connects the second conductive area 304b by a conductive wire 310. The flash LED chip 308 is preferably located on the third conductive area 304c. The n-electrode of the flash LED chip 308 (not shown in FIG. 4) electrically connects the third conductive area 304c and the p-electrode 308a electrically connects the fourth conductive area 304d by a conductive wire 312. Then electrical connection method of the auto-focus LED chip 306, the flash LED chip 308 and these conductive areas 304a, 304b, 304c, 304d is that the p-electrode of the LED chip connects the positive conductive area and the n-electrode of the LED chip connects the negative conductive area.

According to another embodiment of the present invention, different LED chip structures, for example, the LED structure shown in FIG. 1 is used as the auto-focus LED chip and the LED structure shown in FIG. 2 is used as the flash LED chip, and the electrical connection method mentioned above is used to set the auto-focus LED chip and the flash LED chip on the conductive area to drive the auto-focus LED chip and the flash LED chip respectively.

According to one embodiment of the present invention, the auto-focus LED chip 306 and the flash LED chip 308 are preferably close to center of the circuit board 302 to enhance the brightness.

In FIG. 3, the reflector 314 is preferably a reflective plate located on the edge of the circuit board 302 to package the auto-focus LED chip 306 and the flash LED chip 308 therein to reflect light from the auto-focus LED chip 306 and the flash LED chip 308 for enhancing brightness. The reflector 314 is an opaque material. Then, the encapsulant 316 is filled in the reflector 314 to hermetically seal the auto-focus LED chip 306 and the flash LED chip 308. A material of the encapsulant 316 is preferably epoxy resin, acrylic and silica gel.

According to another embodiment of the present invention, fluorescent powder can be added to the encapsulant 316 to mix light from the blue LED with light from the fluorescent powder to illuminate white light. Alternatively, a pervious hemisphere 318 is adhered onto the encapsulant 316 to enhance brightness. The material of the pervious hemisphere 318 is the same as the material of the encapsulant 316.

Thus, the auto-focus LED chip 306 and the flash LED chip 308 are located on the same circuit board to save more space and enhance 50% brightness of the auto-focus LED chip 306.

### Embodiment 2

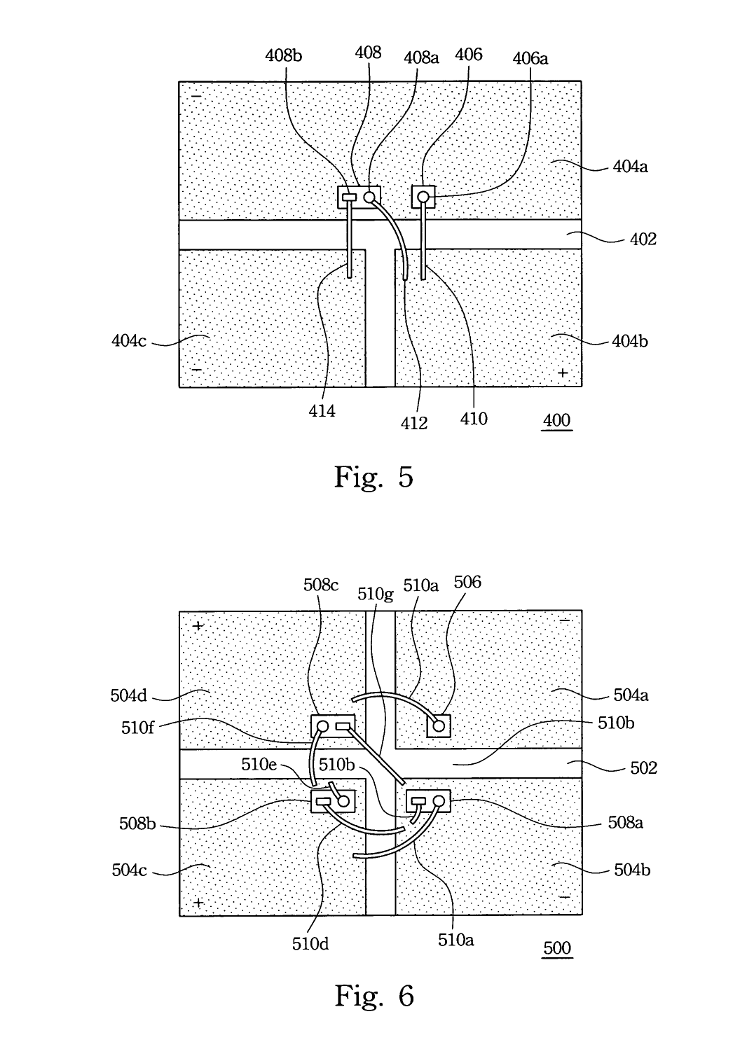

According to another embodiment of the present invention, different LED chip structures can be used to adjust the electrical connection method of the auto-focus LED chip and the flash LED chip on the conductive area. In this embodiment, the LED structure shown in FIG. 1 is used as the auto-focus LED chip and the LED structure shown in FIG. 2 is used as the flash LED chip. FIG. 5 is a top-view diagram showing a surface mounting optoelectronic device according to one embodiment of the present invention. In FIG. 5, a conductive layer (404a, 404b, 404c) is located on a circuit board 402. The conductive layer is divided into a first conductive area 404a, a second conductive area 404b and a third conductive area 404c. The conductive areas (404a, 404b, 404c) are not connected to each other. According to one embodiment of the present invention, electric charge of the first conductive area 404a and the third conductive area 404c is negative, and the electric charge of the second conductive area 404b is positive. A material of the conductive layer is preferably Au, Ag, Cu, Pt, Al, Sn or Mg.

The flash LED chip 408 is the LED structure shown in FIG. 2 so the auto-focus LED chip 406 and the flash LED chip 408 can be set on the same conductive area. According to one embodiment of the present invention, the auto-focus LED chip 406 and the flash LED chip 408 are located on the first conductive area 404a.

The n-electrode of the auto-focus LED chip 406 (not shown in FIG. 5) electrically connects the first conductive area 404a and the p-electrode 406a electrically connects the second conductive area 304b by a conductive wire 410. The p-electrode 408a of the flash LED chip 408 electrically connects the second conductive area 404b by a conductive wire 412 and the n-electrode 408b electrically connects the third conductive area 304c by a conductive wire 414.

According to one embodiment of the present invention, the auto-focus LED chip 406 and the flash LED chip 408 are preferably close to center of the circuit board 402 to enhance the brightness.

Then, a reflector and an encapsulant (not shown in FIG. 5) are sequentially located on the circuit board 402 to hermetically seal the auto-focus LED chip 406 and the flash LED chip 408. The method of positioning the reflector and the encapsulant are preferably the same as the foregoing embodiment, so the description relating to those materials is not repeated here.

### Embodiment 3

According to still another embodiment of the present invention, numbers of the flash LED chips can be increased according to demands to improve brightness. In this embodiment, electrode direction of the auto-focus LED chip and the flash LED chip are preferably the same as the foregoing embodiment 2, so the description relating to those materials is not repeated here. FIG. 6 is a top-view diagram showing a surface mounting optoelectronic device according to one embodiment of the present invention. In FIG. 6, a conductive layer (504a, 504b, 504c, 504d) is located on a circuit board 502. The conductive layer is divided into a first conductive area 504a, a second conductive area 504b, a third conductive area 504c and the fourth conductive area 504d. The conductive areas (504a, 504b, 504c, and 504d) are not connected to each other. According to one embodiment of the present invention, the electric charge of the first conductive area 504a and the second conductive area 504b is negative and the electric charge of the third conductive area 504c and the fourth conductive area 504d is positive. The conductive area material is preferably Au, Ag, Cu, Pt, Al, Sn or Mg.

The auto-focus LED chip 506 is preferably located on the first conductive area 504a. The first flash LED chip 508a, the second flash LED chip 508b and the third flash LED chip 508c are respectively located on the second conductive area 504b, the third conductive area 504c and the fourth conductive area 504d. According to one embodiment of the present invention, the auto-focus LED chip 506, the first flash LED chip 508a, the second flash LED chip 508b and the third flash LED chip 508c are preferably close to center of the circuit board 502 to enhance the brightness.

The auto-focus LED chip 506, the first flash LED chip 508a, the second flash LED chip 508b and the third flash LED chip 508c electrically connect the first conductive area 504a, the second conductive area 504b, the third conductive area 504c and the fourth conductive area 504d respectively by conductive wires 501a to 510g to drive the auto-focus LED chip and the flash LED chip respectively according to the electric property of the auto-focus LED chip 506, the first flash LED chip 508a, the second flash LED chip 508b and the third flash LED chip 508c, and the first conductive area 504a, the second conductive area 504b, the third conductive area 504c and the fourth conductive area 504d. The electric connection method of connecting the auto-focus LED chip with conductive areas and the flash LED chip with conductive areas is preferably the same as the foregoing embodiment, so the description relating to those materials is not repeated here. According to another embodiment of the present invention, the electric connection and LED layout can be changed according to demands.

Then, a reflector and an encapsulant (not shown in FIG. 6) are sequentially located on the circuit board 502 to hermetically seal the auto-focus LED chip 506, the first flash LED chip 508a, the second flash LED chip 508b and the third flash LED chip 508c. The method of positioning the reflector and the encapsulant are preferably the same as the foregoing embodiment, so the description relating to those materials is not repeated here.

Comparing embodiment 1 with embodiment 2, the brightness of the flash LED chip can be enhanced to 200% because three flash LED chips are used.

Thus, the auto-focus LED chip and the flash LED chip are packaged on the same circuit board so that the present invention not only can save more space, but also enhance brightness of the auto-focus LED chip by 50%. Moreover, the present invention can decrease material cost and manufacturing cost. The total decreased cost is about 20%. Furthermore, the present invention not only can obtain multi-function illumination effect on one circuit board, but also increase numbers of LED chips to improve its brightness.

The preferred embodiments of the present invention described above should not be regarded as limitations to the present invention. It will be apparent to those skilled in the art that various modifications and variations can be made to the present invention without departing from the scope or spirit of the invention. The scope of the present invention is as defined in the appended claims.

What is claimed is:

1. A surface mounting optoelectronic device, the device comprising:
a circuit board;
a conductive layer on the circuit board;
at least an auto-focus LED chip on the conductive layer to electrically connect the conductive layer;
at least a flash LED chip on the conductive layer to electrically connect the conductive layer;
a reflector on edge of the circuit board;
an encapsulant in the reflector to hermetically seal the auto-focus LED chip and the flash LED chip.

2. The surface mounting optoelectronic device of claim 1, wherein the conductive layer comprises a first conductive area, a second conductive area, a third conductive area and a fourth conductive area.

3. The surface mounting optoelectronic device of claim 2 wherein positive electrodes of these conductive areas electrically connect the p-electrode of the auto-focus LED chip and the flash LED chip, and negative electrodes of these conductive areas electrically connect n-electrode of the auto-focus LED chip and the flash LED chip.

4. The surface mounting optoelectronic device of claim 1, wherein a material of the conductive layer is selected from a group consisting of Au, Ag, Cu, Pt, Al, Sn and Mg.

5. The surface mounting optoelectronic device of claim 1, wherein a material of the encapsulant is selected from consisting of epoxy resin, acrylic and silica gel.

6. The surface mounting optoelectronic device of claim 1, wherein the reflector comprises an opaque material.

7. The surface mounting optoelectronic device of claim 1, further comprising a pervious hemisphere.

8. A surface mounting optoelectronic device, the device comprising:
a circuit board;
a first conductive area, a second conductive area and a third conductive area on the circuit board;
at least an auto-focus LED chip on the first conductive area to electrically connect the first conductive area and the second conductive area;
at least a flash LED chip on the first conductive area to electrically connect the first conductive area and the second conductive area and the third conductive area, wherein p-electrode of the auto-focus LED and the flash LED chip electrically connect positive electrodes of these conductive areas, and n-electrode of the auto-focus LED and the flash LED electrically connect negative electrodes of these conductive areas;
a reflector on the edge of the circuit board;
an encapsulant in the reflector to hermetically seal the auto-focus LED chip and the flash LED chip.

9. The surface mounting optoelectronic device of claim 8, wherein a material of the conductive layer is selected from a group consisting of Au, Ag, Cu, Pt, Al, Sn and Mg.

10. The surface mounting optoelectronic device of claim 8, wherein a material of the encapsulant is selected from a group consisting of epoxy resin, acrylic and silica gel.

11. The surface mounting optoelectronic device of claim 8, wherein the reflector comprises an opaque material.

12. The surface mounting optoelectronic device of claim 8, further comprising a pervious hemisphere.
